(19) United States
(12) Patent Application Publication
(10) Pub. No.: US 2023/0207386 A1
(43) Pub. Date: Jun. 29, 2023

(54) METHOD OF INCREASING RESISTIVITY OF SILICON CARBIDE WAFER AND HIGH-FREQUENCY DEVICE AND METHOD OF MANUFACTURING THE SAME

(71) Applicant: INDUSTRIAL TECHNOLOGY RESEARCH INSTITUTE, Hsinchu (TW)

(72) Inventors: Mao-Nan CHANG, Hsinchu City (TW); Ta-Ching HSIAO, Zhudong Township (TW); Kuo-Lun HUANG, Hsinchu City (TW); Pei-Ying CHEN, Taoyuan City (TW)

(73) Assignee: INDUSTRIAL TECHNOLOGY RESEARCH INSTITUTE, Hsinchu (TW)

(21) Appl. No.: 18/065,260

(22) Filed: Dec. 13, 2022

Related U.S. Application Data
(60) Provisional application No. 63/294,162, filed on Dec. 28, 2021.

(51) Int. Cl. H01L 21/768; H01L 21/02; H01L 29/16

(52) U.S. Cl. CPC H01L 21/76825; H01L 21/02167; H01L 21/0231; H01L 29/1608

(57) ABSTRACT

A method of increasing the resistivity of a silicon carbide wafer includes providing a silicon carbide wafer with a first resistivity, and applying a microwave to treat the silicon carbide wafer. The treated silicon carbide wafer has a second resistivity. The second resistivity is higher than the first resistivity. The microwave treated silicon carbide wafer can be applied in a high-frequency device.

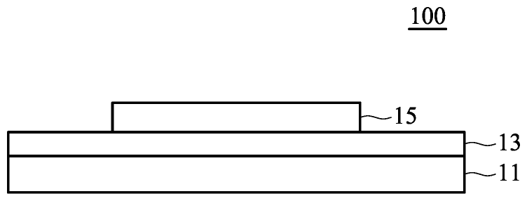

### CROSS REFERENCE TO RELATED APPLICATIONS

This application claims the benefit of U.S. Provisional Application No. 63/294,162, filed on Dec. 28, 2021, which is incorporated by reference herein.

### TECHNICAL FIELD

The technical field relates to a method of increasing the resistivity of a silicon carbide wafer and a high-frequency device utilizing the silicon carbide wafer.

### BACKGROUND

Silicon carbide is a rapidly developing semiconductor wafer material, and is mainly divided into two types, depending on its application. Conductive silicon carbide substrates are used to fabricate high-power devices, and semi-insulating (S. I.) silicon carbide substrates are used to fabricate radio-frequency devices. Gallium nitride (GaN) should furthermore be epitaxially grown on the semi-insulating silicon carbide substrates, and radio frequency devices such as high electron mobility transistors are fabricated on GaN epitaxial layer. Radio frequency elements with both high power and high-frequency are the core of the power amplifier (PA) in the new generation of 5G mm wave communications. Therefore, the semi-insulation silicon carbide wafer is a critical material in 5G communications.

The resistivity of a semi-insulation silicon carbide wafer is between the resistivity of a semiconductor and the resistivity of an insulator, or at least 1E5 Ω·cm or even 1E12 Ω·cm. The conductive impurity element concentration of the silicon carbide wafer should be controlled in low level to achieve high resistivity. This is especially true for the nitrogen element that can easily cause conductive effects in the silicon carbide lattice.

However, the nitrogen content in air and in the environment is very rich, it is very difficult to keep the nitrogen content in the process and the material to an extremely low level. In addition, silicon carbide is one kind of IV group semiconductors, and the nitrogen of the V group has a very high solid solubility (at least 1E20 atoms/cm³) in the silicon carbide lattice. As such, it is not easy to remove the nitrogen from the silicon carbide lattice. The silicon carbide has a strong covalent bonding, and most of the impurity elements such as nitrogen diffuse slowly in the silicon carbide lattice. The diffusion coefficient of nitrogen in the silicon carbide lattice at 1800° C. is only 3E-11 cm² S⁻¹, which also increase the difficulty of separating nitrogen from the silicon carbide.

The major method of increasing the resistivity of a silicon carbide wafer at present is to increase the purity of the raw materials, or doping other dopants to lower the conductive effect of the nitrogen impurities. However, increasing the purity of the raw materials will dramatically increase the cost of raw materials. The process of doping with other dopants should be adjusted to correspond to different nitrogen impurity concentrations, which will increase the cost of processing. Accordingly, a novel method is called for to increase the resistivity of the silicon carbide wafer without dramatically changing the existing process for manufacturing the silicon carbide wafer.

### SUMMARY

One embodiment of the disclosure provides a method of increasing the resistivity of a silicon carbide wafer, including providing a silicon carbide wafer with a first resistivity; and applying a microwave to treat the silicon carbide wafer, wherein the treated silicon carbide wafer has a second resistivity. The second resistivity is higher than the first resistivity.

In some embodiments, the ratio of first resistivity to second resistivity is 1:1.5 to 1:100.

In some embodiments, the silicon carbide wafer has a nitrogen impurity concentration of 1E14 atoms/cm³ to 1E 18 atoms/cm³.

In some embodiments, the first resistivity is greater than 1E5 Ω·cm.

In some embodiments, the second resistivity is 1E7 Ω·cm to 1E12 Ω·cm.

In some embodiments, the microwave has a power of 1000 W to 2400 W.

In some embodiments, the step of applying the microwave is performed in a continuous or segmented manner.

In some embodiments, the step of applying the microwave is performed for a total of 120 seconds to 1200 seconds.

One embodiment provides a method of forming a high-frequency device. The method includes providing a silicon carbide wafer having a first resistivity. The method includes applying a microwave to treat the silicon carbide wafer. The treated silicon carbide wafer has the second resistivity. The second resistivity is higher than the first resistivity. The method includes forming a gallium nitride epitaxial layer on the treated silicon carbide wafer. The method includes forming a high-frequency element on the gallium nitride epitaxial layer.

In some embodiments, the ratio of first resistivity to second resistivity is 1:1.5 to 1:100.

In some embodiments, the silicon carbide wafer has a nitrogen impurity concentration of 1E14 atoms/cm³ to 1E 18 atoms/cm³.

In some embodiments, the first resistivity is greater than 1E5 Ω·cm.

In some embodiments, the second resistivity is 1E7 Ω·cm to 1E12 Ω·cm.

In some embodiments, the microwave has a power of 1000 W to 2400 W.

In some embodiments, the high-frequency element is a high electron mobility transistor.

One embodiment of the disclosure provides a high-frequency device, including a microwave treated silicon carbide wafer having a resistivity of 1E7 Ω·cm to 1E12 Ω·cm; a gallium nitride epitaxial layer deposited on the microwave treated silicon carbide wafer; and a high-frequency element fabricated on the gallium nitride epitaxial layer.

In some embodiments, the microwave treated silicon carbide wafer has a nitrogen impurity concentration of 1E14 atoms/cm³ to 1E 18 atoms/cm³.

In some embodiments, the high-frequency element is a high electron mobility transistor.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGURE shows a high-frequency device in one embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

One embodiment of the disclosure provides a method of increasing the resistivity of a silicon carbide wafer, including providing a silicon carbide wafer with a first resistivity. In some embodiments, the silicon carbide wafer has a nitrogen impurity concentration of 1E14 atoms/cm³ to 1E18 atoms/cm³. The general commercially available silicon carbide wafer without specially controlling the nitrogen impurity concentration may have a nitrogen impurity concentration of greater than 1E18 atoms/cm³. Some skilled in the art may decrease the nitrogen impurity concentration to 1E14 atoms/cm³ to 1E 17 atoms/cm³. In other words, the disclosed method is suitable for a general silicon carbide wafer having a higher nitrogen impurity concentration, and a silicon carbide wafer having a lower nitrogen impurity concentration that is lowered by the well-known skill. As long as the silicon carbide wafer includes a certain degree of nitrogen impurity concentration, the resistivity of the silicon carbide wafer can be increased by the method of the disclosure.

In some embodiments, the first resistivity is greater than 1E5 Ω·cm. The first resistivity is related to the nitrogen impurity concentration. The higher nitrogen impurity concentration means the lower first resistivity. In other words, if the nitrogen impurity concentration of the silicon carbide wafer is too high, the first resistivity will be too low to be adjusted to the desired range (e.g. the second resistivity mentioned below) by the method of the disclosure.

The method further applies a microwave to treat the silicon carbide wafer, wherein the treated silicon carbide wafer has a second resistivity. The second resistivity is higher than the first resistivity. In some embodiments, the ratio of first resistivity to second resistivity is 1:1.5 to 1:100. For example, the second resistivity can be 1E7 Ω·cm to 1E12 Ω·cm. If the second resistivity is too low, it cannot meet the requirements for semi-insulation of a high-frequency device. Note that nitrogen impurity of the silicon carbide wafer is not uniformly distributed, such that different locations of the silicon carbide wafer may have different nitrogen impurity concentrations (and the corresponding resistivity may be different). Therefore, the first resistivity and the second resistivity means the lowest resistivity of a specific location (e.g. the location having the highest nitrogen impurity concentration) of the whole silicon carbide wafer.

In some embodiments, the microwave frequency for treating the silicon carbide wafer is 2.45 GHz. It should be understood that the above microwave frequency is the frequency of the universal microwave equipment, and the disclosure is not limited thereto. One skilled in the art may select another suitable microwave frequency and be not limited to 2.45 GHz. The power of the microwave can be 1000 W to 2400 W. If the microwave power is too high, the silicon carbide wafer may be broken. If the microwave power is too low, the resistivity of the silicon carbide wafer cannot be efficiently increased. In some embodiments, the step of applying the microwave is performed in a continuous or segmented manner, and the total period of applying the microwave is 120 seconds to 1200 seconds. For example, the silicon carbide wafer can be continuous treated by the microwave for a long period such as 800 seconds; be segmented treated by the microwave ten times, each treatment costs 80 seconds, i.e. total 800 seconds; or be segmented treated by the microwave 80 seconds, 100 seconds, 120 seconds, 140 seconds, 160 seconds, 180 seconds, and 200 seconds, i.e. total 800 seconds. If the total period of applying the microwave is too long, the silicon carbide wafer may be broken. If the total period of applying the microwave is too short, the resistivity of the silicon carbide wafer cannot be efficiently increased. Note that not any energy can be applied to the silicon carbide wafer to achieve the above effect. For example, if the silicon carbide wafer is heated to 1000° C. and kept for 10 hours, the resistivity of the silicon carbide wafer cannot be increased.

Accordingly, the disclosure provides a method of increasing the resistivity of the silicon carbide wafer. Compared to the conventional skill, the disclosure does not need to specially reduce the nitrogen impurity concentration in the raw materials, and does not need to additionally dope another dopant into the silicon carbide wafer, thereby reducing the related cost. In other words, the nitrogen impurity concentration of the silicon carbide wafer before the microwave treatment is similar to the nitrogen impurity concentration of the silicon carbide wafer after the microwave treatment, but the microwave treatment may further increase the resistivity of the silicon carbide wafer.

In some embodiments, a method of forming a high-frequency device includes providing a silicon carbide wafer having a first resistivity. The method includes applying a microwave to treat the silicon carbide wafer. The treated silicon carbide wafer has a second resistivity, which is higher than the first resistivity. The above steps are similar to the method of increasing the resistivity of the silicon carbide wafer, and the related description is not repeated here. Subsequently, a gallium nitride epitaxial layer is formed on the treated silicon carbide wafer; and a high-frequency element is formed on the gallium nitride epitaxial layer. If the gallium nitride epitaxial layer is formed on the silicon carbide wafer without being treated by the microwave (and therefore having an overly low resistivity), it may result in problems such as signal loss or current leakage from the element.

As shown in FIGURE, one embodiment of the disclosure provides a high-frequency device 100, including the microwave treated silicon carbide wafer 11 having a resistivity of 1E7 Ω·cm to 1E12 Ω·cm; a gallium nitride epitaxial layer 13 deposited on the microwave treated silicon carbide wafer 11; and a high-frequency element 15 deposited on the gallium nitride epitaxial layer 13. In some embodiments, the high-frequency element 15 is a high electron mobility transistor.

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

### EXAMPLES

### Example 1

Four-point resistivity on a four-inch silicon carbide wafer was measured as 1.92E9 Ω·cm, 2.92E9 Ω·cm, 3.82E9 Ω·cm, and 4.89E9 Ω·cm, respectively. The silicon carbide wafer was cut into three samples A1, A2, and A3. The samples A1, A2, and A3 were treated by a microwave having a microwave frequency of 2.45 GHz and a microwave power of 1800 W, respectively. The sample A was treated four times, and each treatment cost 120 seconds, i.e. total 480 seconds. The sample B was treated eight times, and each treatment cost 90 seconds, i.e. total 720 seconds. The sample C was treated eight times, and each treatment cost 60 seconds, i.e. total 480 seconds. Four-point resistivity on the microwave treated samples A1, A2, and A3 was measured. The four-point resistivity of the sample Al was increased to 3.48E11 Ω·cm, 3.59E11 Ω·cm, 5.98E11 Ω·cm, and 6.53E11 Ω·cm, respectively. The four-point resistivity of the sample A2 was increased to 2.88E11 Ω·cm, 3.13E11 Ω·cm, 3.75E11 Ω·cm, and 5.13E11 Ω·cm, respectively. The four-point resistivity of the sample A3 was increased to 2.508E11 Ω·cm, 2.99E11 Ω·cm, 3.26E11 Ω·cm, and 5.23E11 Ω·cm, respectively. Accordingly, the microwave treatment could efficiently increase the resistivity of the silicon carbide wafer.

### Example 2

Multi-point resistivity on a four-inch silicon carbide wafer was measured as 2.02E8 Ω·cm to greater than 1E12 Ω·cm. The silicon carbide wafer was treated by a microwave having a microwave frequency of 2.45 GHz and a microwave power of 1800 W. The silicon carbide wafer was treated eight times, and each treatment cost 90 seconds, i.e. total 720 seconds. Multi-point resistivity on the microwave treated sample was measured. The multi-point resistivity of the silicon carbide wafer was increased to 3.25E8 Ω·cm to greater than 1E12 Ω·cm. Accordingly, the microwave treatment could efficiently increase the resistivity of the silicon carbide wafer.

### Example 3

Multi-point resistivity on a four-inch silicon carbide wafer was measured as 9.23E7 Ω·cm to greater than 1E12 Ω·cm. The silicon carbide wafer was treated by a microwave having a microwave frequency of 2.45 GHz and a microwave power of 1800 W. The silicon carbide wafer was treated eight times, and each treatment cost 90 seconds, i.e. total 720 seconds. Multi-point resistivity on the microwave treated sample was measured. The multi-point resistivity of the silicon carbide wafer was increased to 8.52E9 Ω·cm to greater than 1E12 Ω·cm. Accordingly, the microwave treatment could efficiently increase the resistivity of the silicon carbide wafer.

### Comparative Example 1 (Treatment Period Was Too Long, and the Wafer Was Broken)

Multi-point resistivity on a four-inch silicon carbide wafer was measured as 5E8 Ω·cm to greater than 1E12 Ω·cm. The silicon carbide wafer was treated by a microwave having a microwave frequency of 2.45 GHz and a microwave power of 1800 W. The silicon carbide wafer was treated eight times, and each treatment cost 120 seconds, i.e. total 960 seconds. The microwave treated sample was broken. Accordingly, the microwave treatment period should not be too long.

### Comparative Example 2 (Treatment Period Was Too Short to Increase the Resistivity of the Wafer)

Multi-point resistivity on a four-inch silicon carbide wafer was measured as 2E9 Ω·cm to 5E9 Ω·cm. The silicon carbide wafer was treated by a microwave having a microwave frequency of 2.45 GHz and a microwave power of 1800 W. The silicon carbide wafer was treated for 90 seconds. Multi-point resistivity on the microwave treated sample was measured. The multi-point resistivity of the silicon carbide wafer was 1E9 Ω·cm to 4.8E9 Ω·cm. Accordingly, the resistivity of the silicon carbide wafer could not be increased by an overly short microwave treatment period.

It will be apparent to those skilled in the art that various modifications and variations can be made to the disclosed methods and materials. It is intended that the specification and examples be considered as exemplary only, with the true scope of the disclosure being indicated by the following claims and their equivalents.

What is claimed is:

1. A method of increasing resistivity of a silicon carbide wafer, comprising:
providing a silicon carbide wafer with a first resistivity; and
applying a microwave to treat the silicon carbide wafer,
wherein the treated silicon carbide wafer has a second resistivity higher than the first resistivity.

2. The method as claimed in claim 1, wherein the microwave has a power of 1000 W to 2400 W.

3. The method as claimed in claim 1, wherein the step of applying the microwave is performed in a continuous or segmented manner.

4. The method as claimed in claim 1, wherein the step of applying the microwave is performed for a total of 120 seconds to 1200 seconds.

5. The method as claimed in claim 1, wherein the first resistivity and the second resistivity have a ratio of 1:1.5 to 1:100.

6. The method as claimed in claim 1, wherein the silicon carbide wafer has a nitrogen impurity concentration of 1E14 atoms/cm³ to 1E 18 atoms/cm³.

7. The method as claimed in claim 1, wherein the first resistivity is greater than 1E5 Ω·cm.

8. The method as claimed in claim 1, wherein the second resistivity is 1E7 Ω·cm to 1E12 Ω·cm.

9. A method of forming a high-frequency device, comprising:
providing a silicon carbide wafer having a first resistivity;
applying a microwave to treat the silicon carbide wafer, wherein the treated silicon carbide wafer has a second resistivity higher than the first resistivity;
forming a gallium nitride epitaxial layer on the treated silicon carbide wafer; and
forming a high-frequency element on the gallium nitride epitaxial layer.

10. The method as claimed in claim 9, wherein the first resistivity and the second resistivity have a ratio of 1:1.5 to 1:100.

11. The method as claimed in claim 9, wherein the silicon carbide wafer has a nitrogen impurity concentration of 1E14 atoms/cm³ to 1E 18 atoms/cm³.

12. The method as claimed in claim 9, wherein the first resistivity is greater than 1E5 Ω·cm.

13. The method as claimed in claim 9, wherein the second resistivity is 1E7 Ω·cm to 1E12 Ω·cm.

14. The method as claimed in claim 9, wherein the microwave has a power of 1000 W to 2400 W.

15. The method as claimed in claim 9, wherein the high-frequency element is a high electron mobility transistor.

16. A high-frequency device, comprising:
a microwave treated silicon carbide wafer having a resistivity of 1E7 Ω·cm to 1E12 Ω·cm;
a gallium nitride epitaxial layer disposed on the microwave treated silicon carbide wafer; and
a high-frequency element disposed on the gallium nitride epitaxial layer.

17. The high-frequency device as claimed in claim 16, wherein the microwave treated silicon carbide wafer has a nitrogen impurity concentration of 1E14 atoms/cm³ to 1E 18 atoms/cm³.

18. The high-frequency device as claimed in claim 16, wherein the high-frequency element is a high electron mobility transistor.
